(19) United States
(12) Patent Application Publication
(10) Pub. No.: US 2025/0006581 A1
(43) Pub. Date: Jan. 2, 2025

(54) SEMICONDUCTOR DEVICE

(71) Applicant: WAVEPIA CO., LTD., Hwaseong-si (KR)

(72) Inventor: Sang Hun LEE, Hwaseong-si (KR)

(73) Assignee: WAVEPIA CO., LTD., Hwaseong-si (KR)

(21) Appl. No.: 18/884,445

(22) Filed: Sep. 13, 2024

Related U.S. Application Data
(63) Continuation of application No. PCT/KR2022/007160, filed on May 19, 2022.

(30) Foreign Application Priority Data
Apr. 29, 2022 (KR) 10-2022-0053769

(51) Int. Cl. H01L 23/34; G01K 7/16

(52) U.S. Cl. CPC H01L 23/34; G01K 7/16

(57) ABSTRACT

The present invention relates to a semiconductor device. A semiconductor device, according to the present invention, comprises: a semiconductor substrate; an active layer disposed on the semiconductor substrate; a transistor disposed on the active layer, and at least one temperature-measuring sensor disposed on a partial region of the active layer. Therein: the transistor comprises a drain electrode, a source electrode and a gate electrode, disposed on the semiconductor substrate; and the active layer comprises a channel region formed between the source electrode and the drain electrode on the top of the semiconductor substrate.

### CROSS-REFERENCE TO RELATED APPLICATION

This application is a Continuation of International Application No. PCT/KR2022/007160 filed on May 19, 2022, which claims benefit of priority to Korean Patent Application No. 10-2022-0053769 filed Apr. 29, 2022, the entire contents of which are incorporated herein by reference.

### TECHNICAL FIELD

The present invention relates to a semiconductor device, and more specifically, to a semiconductor device capable of measuring a temperature of a transistor.

### BACKGROUND ART

Recently, a semiconductor power amplifier (PA) technology and a monolithic microwave integrated circuit (MMIC) technology have received much interest in fields such as electric vehicles, autonomous vehicles, 5G, and high-resolution radar.

In particular, various technologies and materials are being developed to transmit and receive data at high output. For example, since gallium nitride (GaN) operates at a high voltage due to its wide energy gap of 3.4 eV, has a high current density and power density, and operates at a high speed, the use of GaN high electron mobility transistor (HEMT) elements as materials for high-frequency, high-output, high-efficiency, and small-sized power amplifier (PA) devices has been rapidly increasing.

However, due to the increasing frequency, output, and efficiency and decreasing sizes of semiconductor devices, more heat is generated in transistors, which reduces the performance and lifetime of the semiconductor devices. Therefore, technologies for accurately measuring the temperatures of semiconductor devices have been actively developed.

However, temperature measurement technologies of conventional semiconductor devices have a problem that a temperature cannot be accurately measured because a temperature-measuring sensor is far away from a gate-channel region of a transistor, which is a main heat generating source.

In addition, the temperature measurement technologies of the conventional semiconductor devices have a problem that a temperature at the highest heat generating source of the transistor cannot be accurately measured because the temperature-measuring sensor is greatly affected by an air temperature.

Meanwhile, the above-described background technology is technical information that the inventor possessed when deriving the present invention or acquired in the process of deriving the present invention, and it cannot necessarily be said to be known technology disclosed to the public before the filing of the present invention.

(Prior Art Document) Korean Patent Registration No. 10-0439891 (Jul. 1, 2004)

### DISCLOSURE

### Technical Problem

The present invention is directed to increasing performance and lifetime of a semiconductor device by accurately measuring the temperature of the semiconductor device without being affected by an air temperature outside the semiconductor device.

In addition, the present invention is directed to accurately measuring the temperature at a highest heat generating source of a transistor by disposing a temperature-measuring sensor adjacent to a gate-channel region.

In addition, the present invention is directed to providing a semiconductor device that achieves cost reduction by forming a temperature-measuring sensor without the need for a separate process or securing of additional space.

Objects of the present invention are not limited to the objects described above, and other objects not described will be clearly understood by those skilled in the art from the following description.

### Technical Solution

To achieve the object, a semiconductor device according to one embodiment of the present invention includes a semiconductor substrate, an active layer disposed on the semiconductor substrate, a transistor disposed on the active layer, and at least one temperature-measuring sensor disposed on a partial region of the active layer, wherein the transistor includes a gate electrode, a source electrode, and a drain electrode that are disposed on the semiconductor substrate, and the active layer includes a channel region formed between the source electrode and the drain electrode on the semiconductor substrate.

According to another feature of the present invention, the semiconductor device may further include at least one pad disposed on the active layer, wherein the at least one pad may include at least one temperature-measuring pad, and the temperature-measuring pad may be connected to the temperature-measuring sensor and may receive temperature information about the transistor from the temperature-measuring sensor.

According to still another feature of the present invention, the source electrode and the drain electrode may be in ohmic contact with the active layer, and the temperature-measuring sensor may be grounded to a ground electrode disposed under the semiconductor substrate.

According to yet another feature of the present invention, the temperature-measuring sensor may be spaced apart from the closest electrode to the temperature-measuring sensor of the source electrode and the drain electrode by 0.5 to 5 times a width of the closest electrode.

According to yet another feature of the present invention, the temperature-measuring sensor may be disposed inside the channel region.

To achieve the object, a semiconductor device according to another embodiment of the present invention includes a semiconductor substrate, an active layer disposed on the semiconductor substrate, a plurality of transistor units including at least one transistor disposed on the active layer, and at least one temperature-measuring sensor disposed on a partial region of the active layer, wherein the transistor includes a gate electrode, a source electrode, and a drain electrode that are disposed on the semiconductor substrate, and the active layer includes a channel region formed between the source electrode and the drain electrode on the semiconductor substrate.

According to another feature of the present invention, the semiconductor device may further include at least one pad disposed on the active layer, wherein the at least one pad may include at least one temperature-measuring pad, and the temperature-measuring pad may be connected to the temperature-measuring sensor and may receive temperature information about the transistor from the temperature-measuring sensor.

According to still another feature of the present invention, the source electrode and the drain electrode may be in ohmic contact with the active layer, and the temperature-measuring sensor may be grounded to a ground electrode disposed under the semiconductor substrate.

According to yet another feature of the present invention, the semiconductor device may further include a transistor array including the at least one transistor unit, wherein the temperature-measuring sensor may be spaced apart from the closest electrode to the temperature-measuring sensor among the source electrode and the drain electrode by 0.5 to 5 times a width of the closest electrode.

According to yet another feature of the present invention, the plurality of transistor units may be spaced apart from each other, the temperature-measuring sensor may be disposed between the plurality of transistor units, one side of the temperature-measuring sensor may be spaced apart from the closest electrode to the one side by 0.5 to 5 times a width of the closest electrode, and the other side corresponding to the one side of the temperature-measuring sensor may be spaced apart from the closest adjacent electrode to the other side of the temperature-measuring sensor in the transistor unit adjacent to the transistor unit including the closest electrode by 0.5 to 5 times a width of the closest adjacent electrode.

### Advantageous Effects

According to one of the problem-solving means of the present invention, since a temperature-measuring sensor is disposed in an active layer and disposed close to a channel region of a transistor that is a main heat generating source, it is possible to accurately measure the temperature.

According to one of the problem-solving means of the present invention, a semiconductor device can accurately and precisely measure the temperature at the highest heat generating source of a transistor without being affected by the temperature of the external air due to a metal layer deposited to cover an upper surface of a temperature-measuring sensor.

According to one of the problem-solving means of the present invention, since a temperature-measuring sensor is formed in the same process as a process of forming an active layer, it is possible to reduce the number of processes and costs required to arrange the temperature-measuring sensor in a semiconductor device.

The effects obtainable from the present invention are not limited to the above-described effects, and other effects that are not mentioned will be able to be clearly understood by those skilled in the art to which the present invention pertains from the following description.

### DESCRIPTION OF DRAWINGS

FIG. 1 is a plan view of a semiconductor device according to one embodiment of the present invention.

FIG. 2 is a cross-sectional view taken along chain line II-II′ of FIG. 1.

FIG. 3 is a plan view of a semiconductor device according to another embodiment of the present invention.

FIG. 4 is a cross-sectional view taken along chain line IV-IV′ of FIG. 3.

FIG. 5 is a plan view of a semiconductor device according to still another embodiment of the present invention.

FIG. 6 is a cross-sectional view taken along chain line VI-VI′ of FIG. 5.

FIG. 7 is a plan view of a semiconductor device according to yet another embodiment of the present invention.

FIG. 8 is a cross-sectional view taken along chain line VIII-VIII′ of FIG. 7.

FIG. 9 is a cross-sectional view taken along chain line IX-IX′ of FIG. 7.

### MODES OF THE INVENTION

Advantages and features of the present invention and methods of achieving them will become clear by referring to the embodiments described below in detail in conjunction with the accompanying drawings. However, the present invention is not limited to the embodiments disclosed below and can be implemented in various different forms, and these embodiments are merely provided to make the disclosure of the present invention complete and fully inform those skilled in the art to which the present invention pertains of the scope of the present invention, and the present invention is only defined by the scope of the appended claims.

Since shapes, sizes, ratios, angles, numbers, and the like disclosed in the drawings for describing the embodiments of the present invention are exemplary, the present invention is not limited to the illustrated items. In addition, in describing the present invention, when it is determined that the detailed description of a related known technology may unnecessarily obscure the gist of the present invention, the detailed description thereof will be omitted. When the terms “comprise,” “includes,” “have,” and “consists of” described in the present specification are used, other parts may be added unless “only” is used. When a component is expressed in the singular, the plural is included unless otherwise specifically stated.

When interpreting a component, it is interpreted to include a margin of error unless otherwise specifically stated.

Although terms such as “first” and “second” are used to describe various components, the components are not limited by the terms. These terms are merely used to distinguish one component from another. Therefore, a first component described below may be a second component within the technical spirit of the present disclosure.

The same reference numerals indicate the same components throughout the specification unless otherwise specifically stated.

Features of various embodiments of the present disclosure can be partially or fully coupled or combined, and as can be fully understood by those skilled in the art, various technical interconnections and operations are possible, and the embodiments can be implemented independently of each other and implemented together in combination thereof.

Hereinafter, the present application will be described in detail with reference to the accompanying drawings.

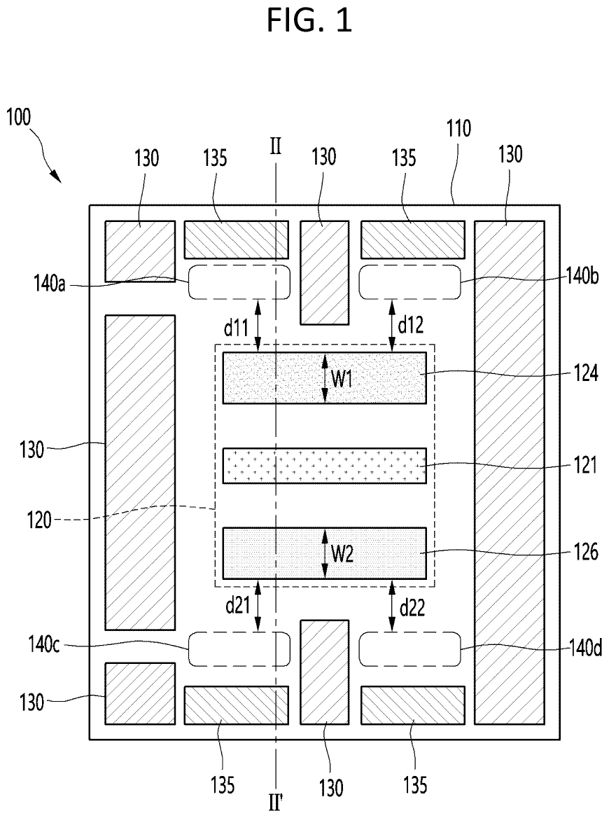

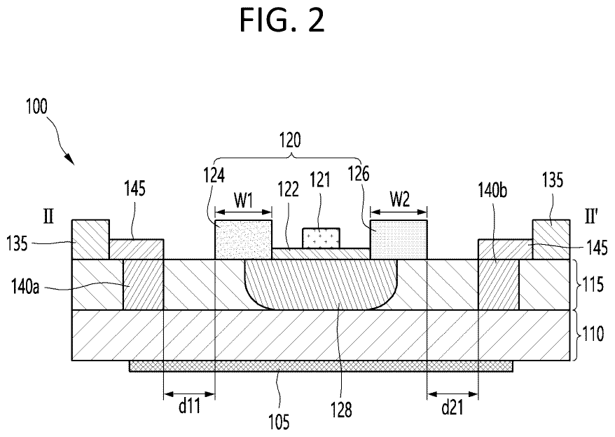

FIG. 1 is a plan view of a semiconductor device according to one embodiment of the present invention, and FIG. 2 is a cross-sectional view taken along chain line II-II′ of FIG. 1.

First, referring to FIGS. 1 and 2, a semiconductor device 100 includes a semiconductor substrate 110, an active layer 115, a transistor 120, and at least one temperature-measuring sensor 140.

Referring to FIG. 1, the transistor 120 is disposed at a center of the semiconductor substrate 110 and includes a source electrode 124 and a drain electrode 126 disposed at both sides of a gate electrode 121 with respect to the gate electrode 121. A plurality of pads 130 including a temperature-measuring pad 135 are disposed to surround the transistor 120, and the temperature-measuring sensor 140 is disposed between one end of the transistor 120 and the temperature-measuring pad 135.

Referring to FIG. 2, the semiconductor substrate 110 is disposed on a ground electrode 105, and the active layer 115 is disposed on the semiconductor substrate 110. The transistor 120 is disposed on the active layer 115 and includes the gate electrode 121, an oxide film 122 disposed between the gate electrode 121 and the active layer 115, the source electrode 124, and the drain electrode 126. A channel region 128 may be formed when a voltage is applied to the gate electrode 121 and the drain electrode 126 and current flows between the source electrode 124 and the drain electrode 126. The temperature-measuring pads 135 are disposed at both ends of the active layer 115. The temperature-measuring sensor 140 is disposed between one end of the transistor 120 and the temperature-measuring pad 135 and inside the active layer 115. A metal layer 145 is disposed on a partial region on the temperature-measuring sensor 140 and on a partial region on the active layer 115, and disposed to be in contact with a portion of the temperature-measuring pad 135.

Referring to FIGS. 1 and 2, the semiconductor substrate 110 may be made of various materials such as Si, SiC, Al₂O₃, GaAs, InP, InAs, and InSb. In addition, an oxide film dielectric layer may be further disposed inside the semiconductor substrate 110. In addition, the semiconductor substrate 110 may undergo processes such as oxidation, photolithography, etching, and thin-film forming.

The ground electrode 105 is an electrode connected to the ground to have a potential of zero. Referring to FIG. 2, the ground electrode 105 may be disposed only in a partial region under the semiconductor substrate 110. The ground electrode 105 may be connected to at least one component of the semiconductor device 100, and preferably connected to the source electrode 124. When the ground electrode 105 is connected to the temperature-measuring sensor 140, since only one measuring terminal outside the semiconductor device 100 may be used when the measuring terminal outside the semiconductor device 100 measures a voltage at the temperature-measuring pad 135, it is possible to save costs. The ground electrode 105 is a conductive material and may be made of a material with high electrical conductivity such as gold (Au).

The active layer 115 is a layer in which the channel region 128 is located in a cross-sectional view of the semiconductor device 100 in which the transistor 120 is disposed. Referring to FIG. 2, the active layer 115 is disposed on the semiconductor substrate 110. Through an arrangement of the active layer 115, the transistor 120 of the semiconductor device 100 may be formed of a plurality of layers. In addition, the temperature-measuring sensor 140 may be disposed in a portion of the active layer 115, and the transistor 120, the temperature-measuring pad 135, and the metal layer 145 may be disposed above the active layer 115.

The channel region 128 is formed while electrons or holes move in a portion of the active layer 115 when a specific voltage is applied to the gate electrode 121, the source electrode 124, and the drain electrode 126. The channel region 128 may be formed in the portion of the active layer 115.

The active layer 115 may be made of various materials depending on types of the semiconductor substrate 110 and the transistor 120. The active layer 115 may be formed by undergoing processes such as epitaxial growth in which Ga, a group III element, and N, a group V element is supplied to the semiconductor substrate 110. Accordingly, a material of the active layer 115 may be a compound including group III and group V elements. For example, the material of the active layer 115 may be AlGaN, GaN, or GaAs. The active layer 115 may have thermal conductivity and transfer the temperature of the channel region 128 to the temperature-measuring sensor 140.

Referring to FIGS. 1 and 2, the transistor 120 is disposed on the active layer 115 and disposed to be surrounded by the plurality of pads 130 including the temperature-measuring pad 135. The transistor 120 includes the gate electrode 121, the oxide film 122, the source electrode 124, and the drain electrode 126. The arrangement and structure of the transistor 120 are shown and described as a MOSFET structure for convenience of explanation, but are not limited thereto and may be replaced with various arrangements and structures of transistors. For example, the transistor 120 may be disposed in a predetermined region on the semiconductor substrate 110 and may have a high-electron-mobility transistor (HEMT) structure or a structure partitioned into an upper electrode and a lower electrode. The transistor 120 may amplify signals by controlling a flow of a current or voltage or perform a current switching function.

Referring to FIG. 2, the gate electrode 121 may be polycrystalline silicon disposed by being deposited on the oxide film 122. The gate electrode 121 may be insulated by the oxide film 122 disposed between the active layer 115 and the gate electrode 121. When a voltage is applied to the gate electrode 121, the gate electrode 121 may serve to control the conductivity of the channel region 128.

Referring to FIG. 2, the oxide film 122 is disposed between the source electrode 124 and the drain electrode 126 and under the gate electrode 121, on the active layer 115. The oxide film 122 may be formed as the semiconductor substrate 110 undergoes an oxidation process and may be made of an oxide. Preferably, the oxide film 122 may be made of SiO₂. The oxide film 122 serves as a gate insulator that prevents a current from flowing between the gate electrode 121 and the channel region 128. However, depending on a formation process of the semiconductor device 100, an arrangement, such as a horizontal or vertical arrangement, and a function, such as an insulating or dielectric property, of the oxide film 122 may be very diverse, and thus it is not limited to the arrangements or functions of the present embodiment.

Referring to FIG. 2, the source electrode 124 and the drain electrode 126 are disposed on the active layer 115. The source electrode 124 and the drain electrode 126 are disposed to be spaced apart from the gate electrode 121 with respect to the gate electrode 121 on the active layer 115.

The source electrode 124 and the drain electrode 126 may be made of the same material. Specifically, the source electrode 124 and the drain electrode 126 may be made of a metal. Accordingly, the source electrode 124 and the drain electrode 126 may be in ohmic contact with the active layer 115. The source electrode 124 and the drain electrode 126 are symmetrical elements, and the transistor 120 may operate normally even when locations of the source electrode 124 and the drain electrode 126 are changed.

When a voltage is applied between the drain electrode 126 and the source electrode 124, a drain current flows, and the drain current may be controlled by a voltage applied between the gate electrode 121 and the source electrode 124. In the above case, a linear relationship may be formed between the voltage and current applied to the drain electrode 126, and in this case, the source electrode 124 and the drain electrode 126 may operate like a variable resistor. The source electrode 124 serves to supply charge carriers to the channel region 128, and the drain electrode 126 serves to absorb the charge carriers.

The channel region 128 is a region in which electrons may flow in the transistor 120. Referring to FIGS. 1 and 2, the channel region 128 is formed in the form of a thin layer in a region of the active layer 115 under the oxide film 122 and between the active layer 115 under the source electrode 124 and the active layer 115 under the drain electrode 126.

The channel region 128 is formed by an electric field generated by applying a voltage to the gate electrode 121. Specifically, the channel region 128 may be formed when a voltage higher than a threshold voltage is applied to the gate electrode 121 and a voltage is applied to the drain electrode 126. Subsequently, as the voltage applied to the gate electrode 121 increases, a carrier concentration in the channel region 128 may increase, thereby increasing conductivity. The channel region 128 has conductivity and a predetermined resistance. Generally, since a change in potential that occurs when a voltage is applied to or cut off from the gate electrode 121 generates the most thermal energy in the transistor 120, a region of the channel region 128 close to the gate electrode 121 may be a portion with the highest temperature in the semiconductor device 100.

The pad 130 is a portion in which a measuring terminal outside the semiconductor device 100 is electrically connected to the semiconductor device 100. Referring to FIG. 1, the pad 130 is disposed to surround the transistor 120 outside the semiconductor device 100. The pad 130 may be made of a metal, and may transmit information about a temperature, RF characteristics, etc. of the semiconductor device 100 to the outside of the semiconductor device 100, and supply various electrical signals, voltages, currents, etc. supplied from the outside to the semiconductor device 100.

Referring to FIGS. 1 and 2, the temperature-measuring pad 135 is disposed outside the semiconductor device 100 and on the active layer 115. The temperature-measuring pad 135 is a portion of at least one of the pads 130 and transmits the temperature information about the semiconductor device 100 to the outside of the semiconductor device 100. The temperature-measuring pad 135 may be electrically connected to the temperature-measuring sensor 140 to receive temperature information about the transistor 120 from the temperature-measuring sensor 140.

Here, the temperature information about the transistor 120 is electrical properties of the temperature-measuring sensor 140 that vary depending on heat generated from the transistor 120. For example, the temperature information about the transistor 120 may be resistance or capacitance of the temperature-measuring sensor 140 that changes due to the heat generated from the transistor 120. Therefore, the measuring terminal outside the semiconductor device 100 is electrically connected to the temperature-measuring pad 135 to measure a voltage of the temperature-measuring sensor 140 or measure resistance of the temperature-measuring sensor 140 by applying a current to the temperature-measuring sensor 140, and thus may receive the temperature information about the transistor 120 as an electrical signal through a change in resistance or capacitance of the temperature-measuring sensor 140.

The arrangement, number, or shape of the temperature-measuring pad 135 is not limited to the arrangement shown in FIGS. 1 and 2, and the temperature-measuring pad 135 may be disposed in consideration of a contact location with an external measuring terminal and a spacing and connection relationship with the temperature-measuring sensor 140. As the temperature-measuring pad 135 and the temperature-measuring sensor 140 are disposed closer, heat generated from the channel region 128 may be transferred to the temperature-measuring sensor 140 with less loss, and thus the temperature of the channel region 128 that is the highest heat generating portion may be accurately and precisely measured.

Referring to FIGS. 1 and 2, the temperature-measuring sensor 140 is disposed between one end of the transistor 120 and the temperature-measuring pad 135 and disposed to be inserted into a portion of the active layer 115. Preferably, the temperature-measuring sensor 140 may be disposed to be spaced apart from the closest electrode to the temperature-measuring sensor 140 among the source electrode 124 and the drain electrode 126 by 0.5 to 5 times a width of the closest electrode. For example, the closest electrode to the plurality of temperature-measuring sensors 140a and 140b is the source electrode 124, and spacings d11 and d12 between each of the plurality of temperature-measuring sensors 140a and 140b and the source electrode 124 are 0.5 to 5 times a width w1 of the source electrode 124.

Only when the temperature-measuring sensor 140 is spaced a predetermined spacing or more from the transistor 120, it is easy to manufacture the semiconductor device 100 and the temperature-measuring sensor 140 does not impair the RF characteristics of the semiconductor device 100. In addition, only when the temperature-measuring sensor 140 is sufficiently close to the transistor 120, the temperature of the highest heat generating portion of the transistor 120 can be accurately measured. Therefore, more preferably, the temperature-measuring sensor 140 may be disposed to be spaced apart from the closest electrode to the temperature-measuring sensor 140 among the source electrode 124 and the drain electrode 126 by 0.9 to 1.1 times the width of the closest electrode. Even more preferably, the temperature-measuring sensor 140 may be disposed to be spaced apart from the closest electrode to the temperature-measuring sensor 140 among the source electrode 124 and the drain electrode 126 by the width of the closest electrode.

Referring to FIG. 2, the temperature-measuring sensor 140 is disposed in a partial region of the active layer 115. Since the temperature-measuring sensor 140 is formed to be inserted into the active layer 115 during a process of forming the active layer 115, the number of additional processes required to arrange the temperature-measuring sensor 140 in the semiconductor device 100 can be reduced and costs can also be saved accordingly.

The temperature-measuring sensor 140 may be made of a material with electrical properties varying depending on a temperature. The temperature-measuring sensor 140 may be a p-n junction diode with an output voltage varying depending on a temperature of a junction portion, and may be a transistor other than the transistor 120 that is a main heat generating source in the semiconductor device. Preferably, the temperature-measuring sensor 140 may be a thermal variable resistor or thermal variable capacitor with a resistance value varying depending on a temperature. In this case, the temperature-measuring sensor 140 may be disposed in the active layer 115 with fewer processes and at a lower cost compared to a diode or transistor and may occupy a small space.

The temperature-measuring sensor 140 composed of a thermal variable resistor may be made of various materials. The temperature-measuring sensor 140 may be formed of a thin film resistor (TFR) and made of NiCr or TaN. Preferably, the temperature-measuring sensor 140 may be a mesa resistor. In general, since a mesa resistor has a high temperature coefficient of resistivity (TCR), the temperature-measuring sensor 140 composed of the mesa resistor can measure the temperature of the transistor 120 more accurately.

Referring to FIG. 2, the metal layer 145 is disposed on a region above the temperature-measuring sensor 140 and on a partial region above the active layer 115 and disposed to be in contact with a portion of the temperature-measuring pad 135. The metal layer 145 may be disposed to cover a portion or the entirety of the region above the temperature-measuring sensor 140. The metal layer 145 may be a portion of a barrier metal deposited to prevent contamination of the semiconductor device 100. The metal layer 145 serves to electrically connect the temperature-measuring pad 135 to the temperature-measuring sensor 140.

In addition, the metal layer 145 may be formed so that thermal conductivity of the metal layer 145 is much lower than that of the active layer 115. With this configuration, the temperature-measuring sensor 140 is isolated from external air above the semiconductor device 100 by the metal layer 145, and changes in electrical properties of the temperature-measuring sensor 140 depend more on a temperature change of the channel region 128 than a temperature of the external air heated by the operation of the semiconductor device 100. Therefore, the temperature-measuring sensor 140 can accurately and precisely measure the temperature at the highest heat generating source of the transistor 120.

According to the above-described embodiment, since the temperature-measuring sensor 140 is spaced a predetermined distance from the channel region 128 inside the active layer 115, the heat generated from the channel region 128 that is the highest heat generating portion may be transferred to the temperature-measuring sensor 140 without loss and without impairing the RF characteristics of the semiconductor device 100. As a result, the semiconductor device 100 can accurately and precisely measure the temperature of the highest heat generating portion on its own.

In addition, according to the above-described embodiment, since the temperature-measuring sensor 140 is formed in the same process as a process of forming the active layer 115, the semiconductor device 100 can be used to reduce the number of processes and costs required to arrange the temperature-measuring sensor 140 in the semiconductor device 100.

In addition, according to the above-described embodiment, since the temperature-measuring sensor 140 is electrically connected to the ground electrode 105, only one measuring terminal outside the semiconductor device 100 is needed to measure the voltage of the temperature-measuring sensor 140, thereby saving on costs required to measure the temperature of the semiconductor device 100.

In addition, according to the above-described embodiment, the semiconductor device 100 can accurately and precisely measure the temperature at the highest heat generating source of the transistor 120 without being affected by the temperature of the external air due to the metal layer 145 deposited to cover an upper surface of the temperature-measuring sensor 140 and having low thermal conductivity.

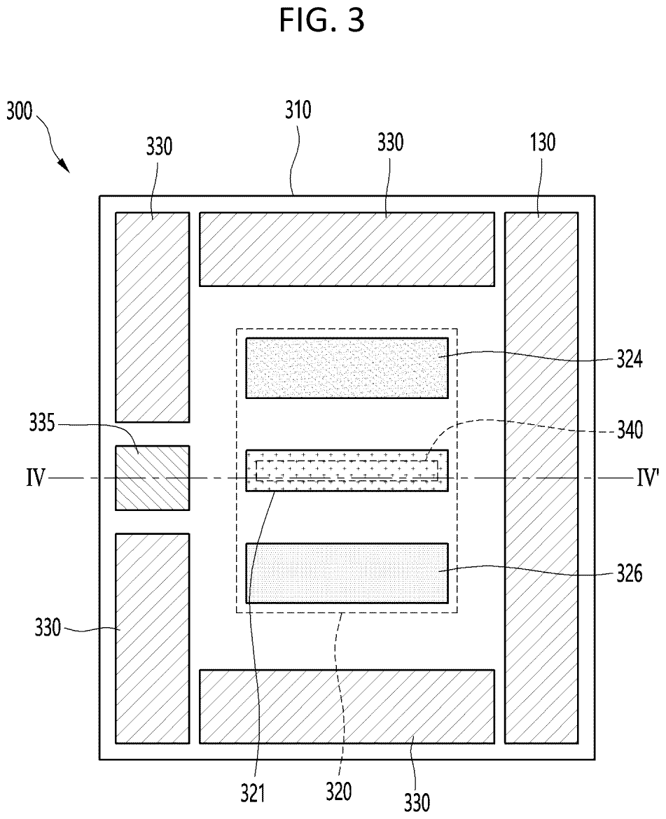

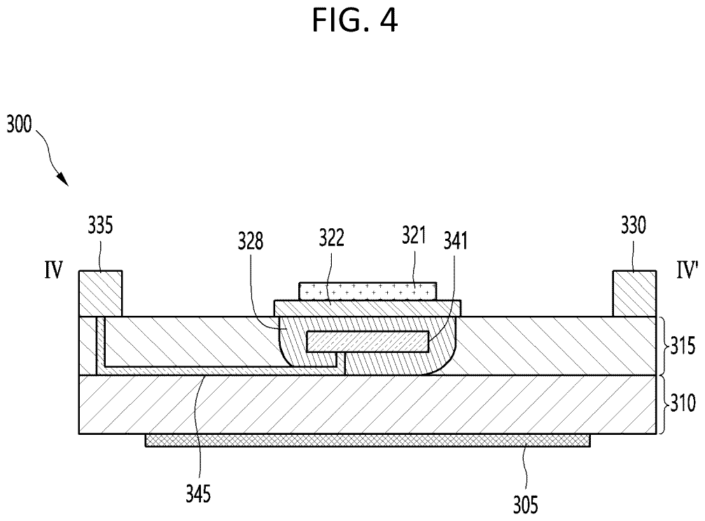

FIG. 3 is a plan view of a semiconductor device according to another embodiment of the present invention, and FIG. 4 is a cross-sectional view taken along chain line IV-IV′ of FIG. 3. When some components of the present embodiment overlap some components of the above-described embodiment, redundant description of the components will be omitted.

Referring to FIGS. 3 and 4, a semiconductor device 300 includes a semiconductor substrate 310, an active layer 315, a transistor 320, and at least one temperature-measuring sensor 340.

Referring to FIGS. 3 and 4, the temperature-measuring sensor 340 is disposed inside a channel region 328 of the semiconductor device 300 and under an oxide film 322. As described above, the highest heat generating source in the transistor 320 may be a region of the channel region 328 close to a gate electrode 321. Accordingly, by arranging the temperature-measuring sensor 340 in the channel region 328 close to the gate electrode 321, the temperature at the highest heat generating source of the transistor 320 can be more accurately measured.

Referring to FIGS. 3 and 4, a temperature-measuring pad 335 may be disposed at one side of the semiconductor device 300 of FIG. 3. Since one temperature-measuring pad 335 is sufficient to measure the electrical properties of the temperature-measuring sensor 340, only one temperature-measuring pad 335 may be disposed, and thus the semiconductor device 300 may be miniaturized or the degree of integration may be increased by additionally arranging other components. In the present embodiment, the temperature-measuring pad 335 is disposed at the left side of the semiconductor device 300 in FIG. 3, but may be free to be disposed to conveniently and accurately measure the electrical properties of the temperature-measuring sensor 340.

As a result, since, compared to a structure in which the temperature-measuring pad 335 is disposed at an upper or lower side of the semiconductor device 300 in FIG. 3, a spacing between the temperature-measuring pad 335 and the temperature-measuring sensor 340 is smaller, the temperature-measuring pad 335 can measure the electrical properties of the temperature-measuring sensor 340 more accurately. In addition, since no other electrodes of the transistor 320 are disposed between the temperature-measuring pad 335 and the temperature-measuring sensor 340, it is easy to electrically connect the temperature-measuring pad 335 to the temperature-measuring sensor 340.

Referring to FIG. 4, a metal layer 345 is disposed from a lower end of the temperature-measuring sensor 340 to a contact surface of the semiconductor substrate 310 and the active layer 315, horizontally disposed in a partial region of the contact surface of the semiconductor substrate 310 and the active layer 315, and disposed from the contact surface of the semiconductor substrate 310 and the active layer 315 to a lower end of the temperature-measuring pad 335. The metal layer 345 electrically connects the temperature-measuring pad 335 to the temperature-measuring sensor 340 so that the temperature-measuring pad 335 may measure the electrical properties of the temperature-measuring sensor 340. That is, the metal layer 345 has the same function as the metal layer 145 in FIG. 2.

According to the above-described embodiment, since the temperature-measuring sensor 340 is disposed adjacent to the region of the channel region 328 close to the gate electrode 321, which is the highest heat generating portion, the semiconductor device 300 can measure the temperature at the highest heat generating source of the transistor 320 very precisely.

In addition, according to the above-described embodiment, since the spacing between the temperature-measuring pad 335 and the temperature-measuring sensor 340 is small and no other electrodes of the transistor 320 are disposed between the temperature-measuring pad 335 and the temperature-measuring sensor 340, it is possible to measure electrical properties more accurately by conveniently connecting the temperature-measuring pad 335 to the temperature-measuring sensor 340.

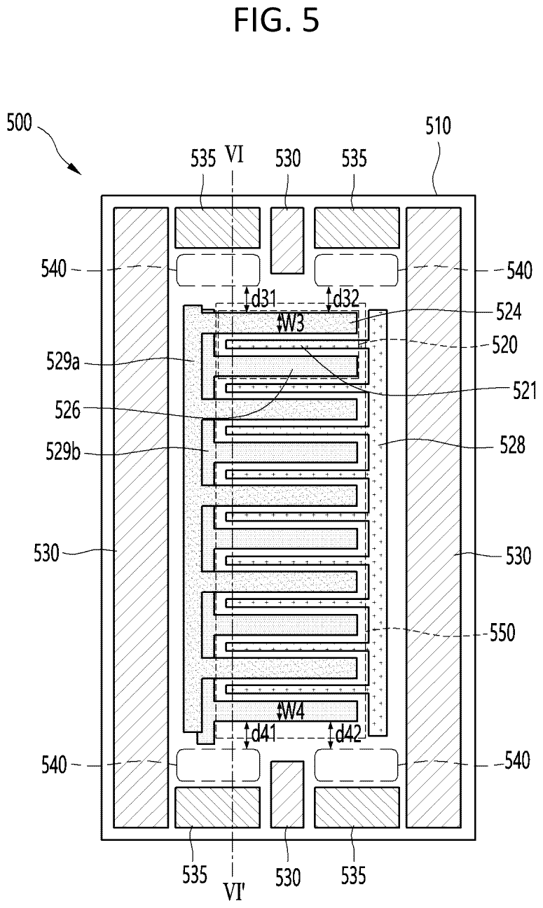

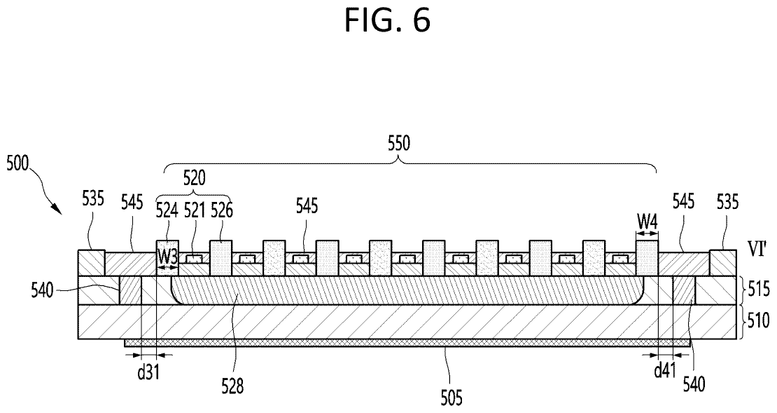

FIG. 5 is a plan view of a semiconductor device according to still another embodiment of the present invention, and FIG. 6 is a cross-sectional view taken along chain line VI-VI′ of FIG. 5. When some components of the present embodiment overlap some components of the above-described embodiments, redundant description of the components will be omitted.

Referring to FIGS. 5 and 6, a semiconductor device 500 includes a semiconductor substrate 510, a transistor array 550 composed of a plurality of transistors 520, and at least one temperature-measuring sensor 540.

Referring to FIG. 5, in the semiconductor device 500, a gate line 528 is disposed in a row between a central portion of the semiconductor device 500 and a right pad 530, and data lines 529a and 529b are disposed in a row between the central portion of the semiconductor device 500 and a left pad 530. A plurality of gate electrodes 521 that extend vertically from the gate line 528 and a plurality of source electrodes 524 and drain electrodes 526 that extend vertically from the data lines 529a and 529b are disposed in parallel with each other to form a plurality of transistors 520. In addition, the plurality of transistors 520 are arranged to form the transistor array 550.

The gate line 528 and the data lines 529a and 529b are merely means to efficiently form the plurality of transistors 520, and thus may be freely disposed according to the properties and configuration of a target semiconductor device.

Each of the plurality of transistors 520 may be designed to have the same electrical characteristics, and the number of the plurality of transistors 520 and a width and length of each electrode may be designed arbitrarily. For example, in the semiconductor device 500, when a current flowing between a source electrode and a drain electrode of any one of the plurality of transistors 520 is smaller than a current flowing between a source electrode and a drain electrode of each of the remaining transistors 520, the electrodes of the any one transistor 520 may be disposed to have decreased or increased widths and lengths.

Referring to FIG. 6, the channel region 528 is formed in the form of a thin layer in a region of the active layer 115 under the transistor array 550 and between the active layer 115 under one end electrode and the active layer 115 under the other end electrode of the transistor array 550. Although one channel region 528 is shown, it is shown for convenience to clearly show the configuration of the present embodiment, and the channel region 528 may be a region in which the plurality of channel regions generated by each transistor 520 of the transistor array 550 overlap.

Referring to FIGS. 5 and 6, the temperature-measuring sensor 540 is disposed between one end of the transistor 520 and the temperature-measuring pad 535 and disposed to be inserted into a portion of the active layer 515. Specifically, the temperature-measuring sensor 540 is disposed between one temperature-measuring pad 535 disposed adjacent to one side of the transistor array 550 and one end of the transistor array 550. Preferably, the temperature-measuring sensor 540 may be disposed to be spaced apart from the closest electrode to the temperature-measuring sensor 540 among the source electrode 524 and the drain electrode 526 by 0.5 to 5 times a width of the closest electrode. For example, the temperature-measuring sensor 540 may be disposed to be spaced d31 apart from the outermost source electrode of the transistor array 550 by 0.5 times a width of the source electrode 524, or the temperature-measuring sensor 540 may be disposed to be spaced d31 apart from the outermost source electrode of the transistor array 550 by 5 times the width of the source electrode 524.

As described above, more preferably, the temperature-measuring sensor 540 may be disposed to be spaced apart from the closest electrode to the temperature-measuring sensor 140 among the source electrode 524 and the drain electrode 526 by 0.9 to 1.1 times the width of the closest electrode. Even more preferably, the temperature-measuring sensor 540 may be disposed to be spaced apart from the closest electrode to the temperature-measuring sensor 540 among the source electrode 524 and the drain electrode 526 by the width of the closest electrode.

Referring to FIG. 6, a metal layer 545 may be disposed over the entire region above the temperature-measuring sensor 540 and the active layer 515 and disposed to be in contact with a portion of the temperature-measuring pad 535.

According to the above-described embodiment, since the temperature-measuring sensor 540 is spaced a predetermined distance from the channel region 528 to receive the temperature of the channel region 128 that is the highest heat generating portion without loss and without impairing the RF characteristics of the semiconductor device 500, the semiconductor device 500 can accurately and precisely measure the temperature of the highest heat generating source.

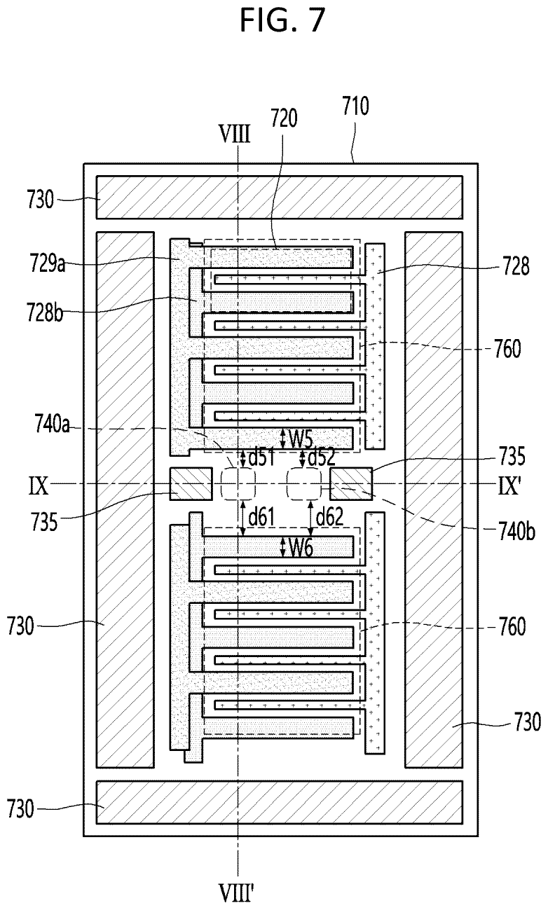

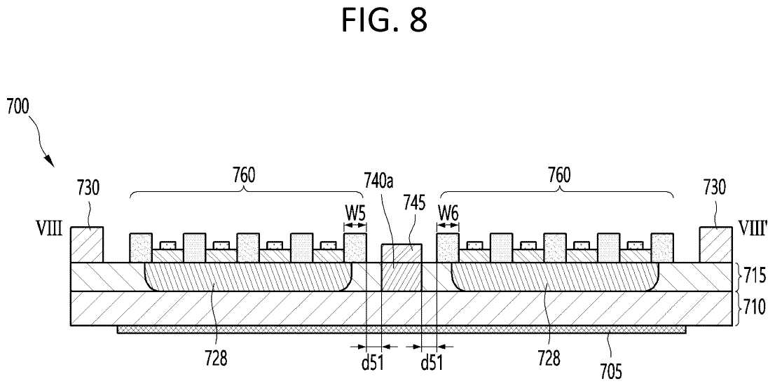

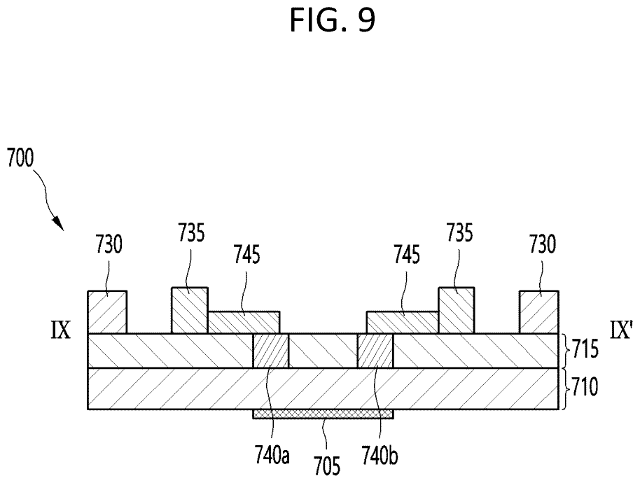

FIG. 7 is a plan view of a semiconductor device according to yet another embodiment of the present invention, FIG. 8 is a cross-sectional view taken along chain line VIII-VIII′ of FIG. 7, and FIG. 9 is a cross-sectional view taken along chain line IX-IX′ of FIG. 7. When some components of the present embodiment overlap some components of the above-described embodiments, redundant description of the components will be omitted.

Referring to FIGS. 7 to 9, a semiconductor device 700 includes a semiconductor substrate 710, a plurality of transistor units 760 composed of a plurality of transistors 720, and at least one temperature-measuring sensor 740 disposed between the plurality of transistor units 760.

Referring to FIG. 7, the plurality of transistors 720 are arranged to form the transistor unit 760.

Referring to FIGS. 7 and 8, two transistor units 760 are spaced apart from each other. Such a configuration may be regarded as the arrangement in which one transistor array 550 of FIGS. 5 and 6 is partitioned into two transistor units 760 and the two transistor units 760 are spaced apart. The number of transistor units 760 may be freely selected as needed.

Referring to FIGS. 7 and 9, a temperature-measuring pad 735 is disposed between the temperature-measuring sensor 740 and a pad 730. As described above, since the temperature-measuring pad 735 may be freely disposed, a spacing between the temperature-measuring pad 735 and the temperature-measuring sensor 740 can be shortened due to the arrangement of the temperature-measuring pad 735, thereby achieving an effect of simplifying connection between the temperature-measuring pad 735 and the temperature-measuring sensor 740.

Referring to FIGS. 7 and 8, the temperature-measuring sensor 740 is disposed between the two transistor units 760 and disposed to be inserted into a portion of an active layer 715. Preferably, one side of the temperature-measuring sensor 740 may be disposed to be spaced apart from the closest electrode to the one side by 0.5 to 5 times a width of the closest electrode, and the other side corresponding to the one side of the temperature-measuring sensor 740 may be disposed to be spaced apart from the closest adjacent electrode to the other side of the temperature-measuring sensor in the transistor unit adjacent to the transistor unit including the closest electrode by 0.5 to 5 times a width of the closest adjacent electrode.

Specifically, spacings d51 and d52 between one side surface of each of the plurality of temperature-measuring sensors 740a and 740b and a source electrode that is the closest electrode are 0.5 to 5 times a width w5 of the source electrode that is the closest electrode to the above one side surface. In addition, spacings d61 and d62 between the other side surface of each of the plurality of temperature-measuring sensors 740a and 740b and a drain electrode that is the closest electrode to the above other side surface are 0.5 to 5 times a width w6 of the drain electrode that is the closest electrode.

As described above, more preferably, the temperature-measuring sensor 740 may be disposed to be spaced apart from the closest electrode to the temperature-measuring sensor 540 among a source electrode 724 and a drain electrode 726 by 0.9 to 1.1 times the width of the closest electrode. Even more preferably, the temperature-measuring sensor 740 may be disposed to be spaced apart from the closest electrode to the temperature-measuring sensor 740 among the source electrode 724 and the drain electrode 726 by the width of the closest electrode.

This configuration corresponds to the arrangement of the temperature-measuring sensor 140 and the closest electrode to the temperature-measuring sensor 140 described in FIGS. 1 and 2.

Referring to FIGS. 8 and 9, a metal layer 745 is disposed on a partial region above the temperature-measuring sensor 740 and disposed to be in contact with a portion of the temperature-measuring pad 735. In addition, since the metal layer 745 corresponding to the temperature-measuring sensor 740a is disposed not to be in contact with the metal layer 745 corresponding to another temperature-measuring sensor 740b, the temperature-measuring sensor 740a is not electrically connected to another temperature-measuring sensor 740b. Therefore, the electrical properties of the temperature-measuring sensor 740a and another temperature-measuring sensor 740b can each be measured separately.

According to the above-described embodiment, since the temperature-measuring sensor 740 is spaced a predetermined distance from a channel region 728 to receive the temperature of the channel region 728 that is the highest heat generating portion without loss and without impairing the RF characteristics of the semiconductor device 700, the semiconductor device 700 can accurately and precisely measure the temperature at the highest heat generating source of the transistor 720.

Meanwhile, in general, a heat generating region of a transistor is greater than an arrangement region of the transistor. Therefore, as the number of closely disposed transistors increases, more of the heat generating regions of the transistors overlap each other, and thus it is difficult to accurately measure the temperature at the highest heat generating source of the semiconductor device. However, as described above, since the plurality of transistor units 760 have substantially the same partitioned and spaced arrangement as one transistor array 550 in FIG. 5, one transistor unit 760 includes fewer transistors 720 than one transistor array 550 in the same area of the semiconductor device 700. Therefore, according to the above-described embodiment, the semiconductor device 700 can measure the temperature more simply than a semiconductor device including one transistor array.

In addition, according to the above-described embodiment, since the temperature-measuring sensor 740 is disposed between the transistor units 760 and close to a center of the semiconductor device 700, it is easy to measure the temperature near the highest heat generating source inside the semiconductor device 700.

Although embodiments of the present invention have been described in more detail with reference to the accompanying drawings, the present invention is not necessarily limited to these embodiments, and various modifications may be made without departing from the technical spirit of the present invention. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects. The scope of the present disclosure should be construed according to the appended claims, and all technical spirits within the equivalent range should be construed as being included in the scope of the present disclosure.

1. A semiconductor device comprising:
a semiconductor substrate;
an active layer disposed on the semiconductor substrate;
a transistor disposed on the active layer; and
at least one temperature-measuring sensor disposed on a partial region of the active layer,
wherein the transistor includes a gate electrode, a source electrode, and a drain electrode that are disposed on the semiconductor substrate, and
the active layer includes a channel region formed between the source electrode and the drain electrode on the semiconductor substrate.

2. The semiconductor device of claim 1, further comprising at least one pad disposed on the active layer,
wherein the at least one pad includes at least one temperature-measuring pad, and
the temperature-measuring pad is connected to the temperature-measuring sensor and receives temperature information about the transistor from the temperature-measuring sensor.

3. The semiconductor device of claim 1, wherein the source electrode and the drain electrode are in ohmic contact with the active layer, and
the temperature-measuring sensor is grounded to a ground electrode disposed under the semiconductor substrate.

4. The semiconductor device of claim 1, wherein the temperature-measuring sensor is spaced apart from the closest electrode to the temperature-measuring sensor among the source electrode and the drain electrode by 0.5 to 5 times a width of the closest electrode.

5. The semiconductor device of claim 1, wherein the temperature-measuring sensor is disposed inside the channel region.

6. A semiconductor device comprising:
a semiconductor substrate;
an active layer disposed on the semiconductor substrate;
a plurality of transistor units including at least one transistor disposed on the active layer; and
at least one temperature-measuring sensor disposed on a partial region of the active layer,
wherein the transistor includes a gate electrode, a source electrode, and a drain electrode that are disposed on the semiconductor substrate, and
the active layer includes a channel region formed between the source electrode and the drain electrode on the semiconductor substrate.

7. The semiconductor device of claim 6, further comprising at least one pad disposed on the active layer,
wherein the at least one pad includes at least one temperature-measuring pad, and
the temperature-measuring pad is connected to the temperature-measuring sensor and receives temperature information about the transistor from the temperature-measuring sensor.

8. The semiconductor device of claim 6, wherein the source electrode and the drain electrode are in ohmic contact with the active layer, and
the temperature-measuring sensor is grounded to a ground electrode disposed under the semiconductor substrate.

9. The semiconductor device of claim 6, further comprising a transistor array including at least one transistor unit,
wherein the temperature-measuring sensor is spaced apart from the closest electrode to the temperature-measuring sensor among the source electrode and the drain electrode by 0.5 to 5 times a width of the closest electrode.

10. The semiconductor device of claim 6, wherein the plurality of transistor units are spaced apart from each other,
the temperature-measuring sensor is disposed between the plurality of transistor units,
one side of the temperature-measuring sensor is spaced apart from the closest electrode to the one side by 0.5 to 5 times a width of the closest electrode, and
the other side corresponding to the one side of the temperature-measuring sensor is spaced apart from the closest adjacent electrode to the other side of the temperature-measuring sensor in the transistor unit adjacent to the transistor unit including the closest electrode by 0.5 to 5 times a width of the closest adjacent electrode.
